(19) United States
(12) Patent Application Publication
(10) Pub. No.: US 2023/0371356 A1
(43) Pub. Date: Nov. 16, 2023

(54) IN-SITU FLASH EVAPORATION FILM FORMING APPARATUS FOR PEROVSKITESOLAR CELL

(71) Applicant: Huaneng Clean Energy Research Institute, Beijing (CN)

(72) Inventors: Xinlian LI, Beijing (CN); Weidong LI, Beijing (CN); Zhiguo ZHAO, Beijing (CN); Xiaojun QIN, Beijing (CN); Dongming ZHAO, Beijing (CN); Yun ZHANG, Beijing (CN); Yuan XIA, Beijing (CN); Jiguang XIONG, Beijing (CN)

(21) Appl. No.: 18/248,419

(22) PCT Filed: Dec. 10, 2021
(86) PCT No.: PCT/CN2021/137045

§ 371 Date: Apr. 10, 2023

(30) Foreign Application Priority Data
Sep. 10, 2021 (CN) 202122197858.X

(51) Int. Cl. H10K 71/00; H10K 30/40; H10K 30/50

(52) U.S. Cl. CPC H10K 71/811; H10K 30/40; H10K 30/50

(57) ABSTRACT

An in-situ flash evaporation film forming apparatus for a perovskite solar cell includes a platform; a substrate disposed on the platform and configured to form a film layer; and a cavity cover movably disposed up and down on the platform, and being able to enclose the substrate into a closed cavity surrounded by the cavity cover and the platform, a vacuum pipe being disposed on the cavity cover and being able to communicate the closed cavity with a vacuum pump.

### CROSS-REFERENCE TO RELATED APPLICATIONS

This application is a U.S. national stage entry of International Application No. PCT/CN2021/137045, filed Dec. 10, 2021, which claims priority to Chinese Patent Application No. 202122197858.X, filed Sep. 10, 2021, the entire disclosures of which are incorporated herein by reference.

### FIELD

The present disclosure relates to the field of film forming technology of perovskite solar cells, and in particular, to an in-situ flash evaporation film forming apparatus for a perovskite solar cell.

### BACKGROUND

Perovskite solar cells are attracting more and more attention due to the advantages of high conversion efficiency, low cost, and environmental friendliness. Moreover, the photoelectric conversion efficiency of perovskite solar energy has increased several times in just a few years, showing excellent photoelectric performance. A method for preparing a film layer of the perovskite solar cell is as follows. A transparent conductive film is prepared on a substrate for an electrode layer on a light receiving side, and then a carrier transport layer is prepared on the transparent conductive film. A perovskite layer is prepared above the carrier transport layer as a light absorption layer, then a carrier transport layer on the other side is prepared on the light absorption layer, and finally a metal layer is prepared as a transparent conductive film on the other side.

In the prior art, the film layer is usually prepared by a scraping process. After scraping, the formed film layer needs to be transferred to a vacuum chamber to remove the solvent, which is a flash evaporation process. In the prior art, an equipment for scraping the film layer and an equipment for flash evaporation are two sets of independent equipment. After the film layer is formed by scraping in the scraping equipment, the formed film layer needs to be transferred to the flash evaporation equipment for flash evaporation. However, in the process of transferring the film layer from the scraping equipment to the flash evaporation equipment, part of the solvent in the film layer will volatilize, which will affect the quality of finished products in a natural state.

Therefore, how to shorten the turnaround time of the film layer, thus preventing the solvent from evaporating in the natural state and ensuring the quality of finished products, is a key problem to be solved urgently by those skilled in the art.

### SUMMARY

To achieve the above-mentioned purpose, the present disclosure provides an in-situ flash evaporation film forming apparatus for a perovskite solar cell. The apparatus includes a platform; a substrate disposed on the platform and configured to form a film layer; and a cavity cover movably disposed up and down on the platform, and being able to enclose the substrate into a closed cavity surrounded by the cavity cover and the platform, a vacuum pipe being disposed on the cavity cover and being able to communicate the closed cavity with a vacuum pump.

In some embodiments, an electromagnetic valve is disposed on the vacuum pipe and configured to open or close the vacuum pipe, and the vacuum pump is in a normally open state.

In some embodiments, a plurality of vacuum pipes are uniformly arranged relative to the substrate.

In some embodiments, a plurality of vacuum pipes are provided, and two or more of the vacuum pipes are connected with the vacuum pump via a connecting pipe, electromagnetic valves are disposed on the connecting pipe, and the vacuum pump is in a normally open state.

In some embodiments, a sealing ring is disposed on the platform and arranged around the substrate, and a sealing ring groove which is matched with the sealing ring is disposed on the cavity cover.

In some embodiments, an adsorption hole is formed in the platform, communicated with a negative pressure pump and configured to adsorb the substrate.

In some embodiments, the apparatus further includes a coating head, in which driving rods are connected with both sides of the coating head, respectively, sliders are connected to the driving rods and fit in slide rails, the slide rails extend in a scraping direction of the coating head, and the driving rods are driven by linear driving devices.

In some embodiments, the linear driving devices are linear motors, and each of the driving rods is driven by one linear motor.

In some embodiments, the cavity cover is driven by a cylinder.

In some embodiments, a fixing plate is disposed above the cavity cover, a guide hole is formed in the fixing plate, and a guide pillar is disposed on an upper surface of the cavity cover and fitted in the guide hole.

### BRIEF DESCRIPTION OF THE DRAWINGS

In order to illustrate the technical solutions in embodiments of the present disclosure more clearly, accompanying drawings used in the description of the embodiments will be briefly introduced below, and it is obvious that the accompanying drawings in the following description are only some embodiments of the present disclosure. For those skilled in the art, other accompanying drawings can also be obtained from these accompanying drawings without creative labor.

FIG. 1 is a schematic diagram showing a state of an in-situ flash evaporation film forming apparatus for a perovskite solar cell provided by an embodiment of the present disclosure at a certain moment during a flash evaporation operation.

FIG. 2 is a schematic diagram showing a state of an in-situ flash evaporation film forming apparatus for a perovskite solar cell provided by an embodiment of the present disclosure at a certain moment during a scraping operation.

FIG. 3 is a top view of a driving rod and a slide rail provided by an embodiment of the present disclosure.

FIG. 4 is a front view of a cavity cover, a fixing plate and a guide pillar provided by an embodiment of the present disclosure.

Reference numerals: 1 is a platform, 2 is a substrate, 3 is a cavity cover, 4 is a vacuum pipe, is an electromagnetic valve, 6 is a coating head, 7 is a cylinder, 8 is a sealing ring, 9 is a slide rail, is a driving rod, 11 is a fixing plate, and 12 is a guide pillar.

### DETAILED DESCRIPTION

The present disclosure discloses an in-situ flash evaporation film forming apparatus for a perovskite solar cell. The apparatus may flash a film layer immediately without changing the position of the film layer, thus preventing the solvent from evaporating in a natural state, and ensuring the quality of finished products.

The technical solutions in embodiments of the present disclosure will be clearly and completely described below with reference to accompanying drawings in the embodiments of the present disclosure. Obviously, the described embodiments are only part of the embodiments of the present disclosure, but not all of the embodiments. Based on the embodiments in the present disclosure, all other embodiments obtained by those skilled in the art without creative labor shall fall within the protection scope of the present disclosure.

In the description of the present disclosure, the orientation or positional relationship indicated by terms “upper”, “lower”, etc. is based on the orientation or positional relationship shown in the accompanying drawings, which is only for the convenience of describing the present disclosure rather than requiring the present disclosure being constructed and operated in a particular orientation, so it cannot be construed as a limitation of the present disclosure.

The present disclosure discloses an in-situ flash evaporation film forming apparatus for a perovskite solar cell. The apparatus includes a platform 1, a substrate 2, and a cavity cover 3. The substrate 2 is disposed on the platform 1 and configured to form a film layer. The cavity cover 3 is movably disposed up and down on the platform 1. The cavity cover 3 surrounds a closed cavity with the platform 1 after being enclosed on the platform 1, and the substrate 2 is located in the closed cavity. That is, the cavity cover 3 is able to enclose the substrate 2 into the closed cavity surrounded by the cavity cover 3 and the platform 1, as shown in FIG. 1. A vacuum pipe 4 is disposed on the cavity cover 3 and is able to communicate the closed cavity with a vacuum pump.

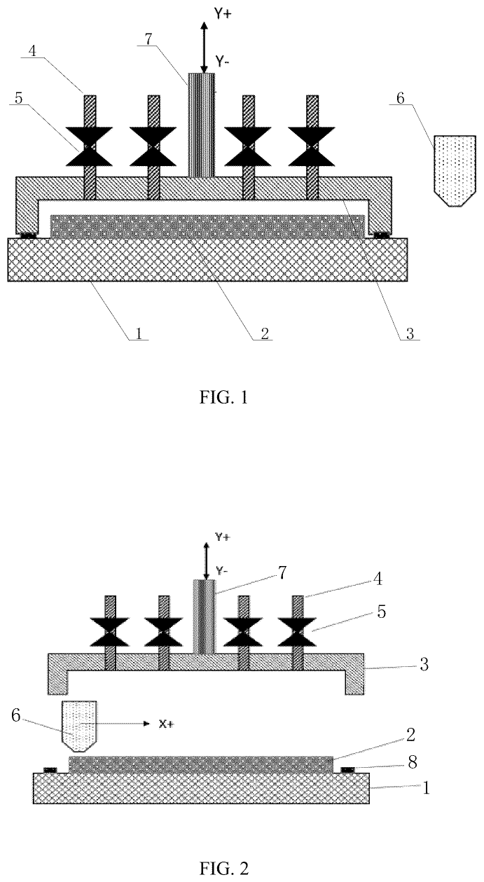

Referring to FIG. 2, in an initial state, the cavity cover 3 is located above the platform 1, and the substrate 2 is exposed to the outside, so that the film layer may be scraped on the substrate 2. After scraping, the cavity cover 3 is moved down, the substrate 2 is enclosed in the closed cavity, the vacuum pump and the vacuum pipe 4 are opened to evacuate the closed cavity, and flash evaporation is performed to remove the solvent. After the film layer is formed, the cavity cover 3 may be directly lowered to perform in-situ flash evaporation on the formed film layer, which saves the turnaround time of the film layer from a film forming equipment to a flash evaporation equipment, thus preventing the solvent from evaporating in the natural state, and further ensuring the quality of finished products.

After the film layer is formed on the substrate 2, in order to prevent the starting up of the vacuum pump from occupying time, thus further preventing the film layer from volatilizing solvent in the natural state, the present disclosure has made the following design. An electromagnetic valve 5 is disposed on the vacuum pipe 4 and configured to open or close the vacuum pipe 4. The vacuum pump is in a normally open state. When the film layer on the substrate 2 is formed, the cavity cover 3 is lowered immediately, and then the electromagnetic valve 5 is opened. Since the vacuum pump is in the normally open state, the closed cavity may be evacuated immediately after the electromagnetic valve 5 is opened.

In order to ensure the uniform pumping speed on a surface of the substrate 2, the present disclosure provides a plurality of vacuum pipes 4, which are uniformly arranged relative to the substrate 2.

The vacuum pipe 4 and the vacuum pump may also be connected in the following way. Two or more of the vacuum pipes 4 are connected with the vacuum pump via a connecting pipe, or all the vacuum pipes 4 may be connected with the vacuum pump via a connecting pipe. The electromagnetic valve 5 is disposed on the connecting pipe, and the vacuum pump is in a normally open state. If vacuuming is required, the closed cavity may be evacuated immediately as long as the electromagnetic valve 5 is opened. By adopting a connection mode in the embodiment, the amount of the electromagnetic valve 5 may be reduced.

In order to ensure the tightness of the closed cavity surrounded by the cavity cover 3 and the platform 1, the present disclosure also makes the following design. A sealing ring 8 is disposed on the platform 1 around the substrate 2, and a sealing ring groove which is matched with the sealing ring 8 is disposed on the cavity cover 3. After the cavity cover 3 has been lowered onto the platform 1, the sealing ring 8 on the platform 1 has just been pressed into the sealing groove.

In order to ensure the stability and accuracy of the up and down movement of the cavity cover 3, the present disclosure also provides a guide pillar 12 and a fixing plate 11, as shown in FIG. 4. The fixing plate 11 is disposed above the cavity cover 3. In some embodiments, the fixing plate 11 may be fixed on a surrounding frame. In addition, the fixing plate 11 may also be fixed on a support frame, and the support frame is disposed on the ground. A guide hole is formed in the fixing plate 11. The guide pillar 12 is disposed on an upper surface of the cavity cover 3 and fixedly connected with the cavity cover 3. The guide pillar 12 is provided in the guide hole. During the movement of the cavity cover 3, the cavity cover 3 may stably move up and down and may be accurately enclosed on the platform 1 under the cooperation of the guide pillars 12 and the guide holes. The sealing ring 8 may accurately enter into the sealing ring groove. The enclosed closed cavity may also be referred to as a preset closed cavity, and the substrate 2 may be accurately enclosed therein.

Based on the consideration of uniform guidance, the present disclosure provides two guide pillars 12, and the two guide pillars 12 are arranged at both ends of the cavity cover 3.

It is to be noted that a coating head 6 for scraping the film layer is provided below the cavity cover 3. Therefore, providing the guide pillar 12 and the fixing plate 11 above the cavity cover 3 may prevent interference with the coating head 6.

It is also to be noted that the up and down movement of the cavity cover 3 may be driven by a cylinder 7. The cylinder 7 is easy to control and has high working precision.

From the above description, it may be seen that the substrate 2 is disposed on the platform 1, and it is necessary to ensure that the substrate 2 is fixed in the process of scraping the film layer. To this end, an adsorption hole is formed in the platform 1. The present disclosure provides a plurality of vacuum pipes, which are uniformly arranged relative to the substrate 2. All adsorption holes are communicated with a negative pressure pump. In the process of scraping the film layer, the negative pressure pump is started to generate negative pressure in the adsorption hole, so that the substrate 2 is firmly adsorbed.

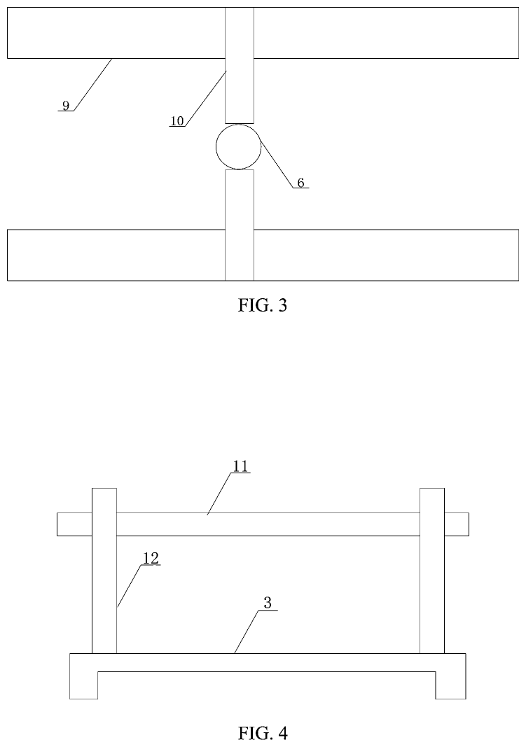

In the art, the coating head 6 is usually used to scrape the film layer on the substrate 2. The coating head 6 needs to be moved from one side of the substrate 2 to the other. In the present disclosure, referring to FIG. 3, a driving mode of the coating head 6 is as follows. Driving rods 10 are connected with both sides of the coating head 6, respectively. Sliders are connected to the driving rods 10 and fit in sliding rails 9. Since there are two driving rods 10, there are correspondingly two sliders and two sliding rails 9. The slide rails 9 extend in a moving direction of the coating head 6. The driving rods 10 are disposed in a direction perpendicular to the sliding rails 9. The driving rods 10 are driven by linear driving devices. The linear driving devices are configured to output a straight line, thus driving the driving rods 10 to move along the sliding rails 9. In the present disclosure, the linear driving devices are preferably linear motors. In addition, there are two linear motors, and each of the driving rods 10 is driven by one linear motor.

From the above description, it may be seen that the coating head 6 is located on one side of the platform 1 before scraping, and the coating head 6 moves to the other side of the platform 1 as scraping proceeds. During the movement of the coating head 6, the cavity cover 3 is located above the substrate 2, and the driving rods 10 and the coating head 6 just pass through a gap between the cavity cover 3 and the substrate 2. After scraping, the coating head 6 stops outside a projection range of the cavity cover 3, so that the cavity cover 3 does not interfere with the coating head 6 or the driving rods 10 during the lowering.

The disposing of the driving rods 10 in the present disclosure not only enables the coating head 6 to realize a linear scraping action, but also ensures that the driving rods 10 does not interfere with the cavity cover 3. In this way, it is possible to ensure that the scraping operation and the vacuuming operation do not interfere with each other, and the scraping operation and the vacuuming operation may be completed in sequence without changing the position of the substrate 2.

It may be seen from the above technical solutions that, in an initial state, the cavity cover is located above the platform, and the substrate is exposed to the outside, so that the film layer may be scraped on the substrate. After scraping, the cavity cover is moved down, the substrate is enclosed in the closed cavity, the vacuum pump and the vacuum pipe are opened to evacuate the closed cavity, and flash evaporation is performed to remove the solvent. After the film layer is formed, the cavity cover may be directly lowered to perform in-situ flash evaporation on the formed film layer, which saves the turnaround time of the film layer from a film forming equipment to a flash evaporation equipment, thus preventing the solvent from evaporating in the natural state, and further ensuring the quality of finished products.

Finally, it is to be noted that the terms “comprising”, “including” or any other variation thereof are intended to cover a non-exclusive inclusion, such that a process, method, article or device that includes a series of elements includes not only those elements, but also other elements that are not explicitly listed, or elements inherent in such a process, method, article or device. An element defined by the phrase “comprising a . . . ” does not exclude the existence of other identical elements in the process, method, article, or device that includes the element without further limitation.

Each embodiment in this description is described in a progressive manner, and each embodiment focuses on differences from other embodiments, and the same and similar parts between the various embodiments may be referred to each other.

The above description of the disclosed embodiments enables those skilled in the art to implement or use the present disclosure. Various modifications to these embodiments will be readily apparent to those skilled in the art, and the generic principles defined herein may be implemented in other embodiments without departing from the spirit or scope of the present disclosure. Therefore, the present disclosure is not intended to be limited to the embodiments shown herein, but is to be accorded the widest scope consistent with the principles and novel features disclosed herein.

What is claimed is:

1. An in-situ flash evaporation film forming apparatus for a perovskite solar cell, comprising:
a platform;
a substrate disposed on the platform and configured to form a film layer; and
a cavity cover movably disposed up and down on the platform, and being able to enclose the substrate into a closed cavity surrounded by the cavity cover and the platform, a vacuum pipe being disposed on the cavity cover and being able to communicate the closed cavity with a vacuum pump.

2. The in-situ flash evaporation film forming apparatus for the perovskite solar cell of claim 1, wherein an electromagnetic valve is disposed on the vacuum pipe and configured to open or close the vacuum pipe, and the vacuum pump is in a normally open state.

3. The in-situ flash evaporation film forming apparatus for the perovskite solar cell of claim 1, wherein a plurality of vacuum pipes are uniformly arranged relative to the substrate.

4. The in-situ flash evaporation film forming apparatus for the perovskite solar cell of claim 1, wherein a plurality of vacuum pipes are provided, and two or more of the vacuum pipes are connected with the vacuum pump via a connecting pipe, electromagnetic valves are disposed on the connecting pipe, and the vacuum pump is in a normally open state.

5. The in-situ flash evaporation film forming apparatus for the perovskite solar cell of claim 1, wherein a sealing ring is disposed on the platform and arranged around the substrate, and a sealing ring groove which is matched with the sealing ring is disposed on the cavity cover.

6. The in-situ flash evaporation film forming apparatus for the perovskite solar cell of claim 1, wherein an adsorption hole is formed in the platform, communicated with a negative pressure pump and configured to adsorb the substrate.

7. The in-situ flash evaporation film forming apparatus for the perovskite solar cell of claim 1, further comprising a coating head, wherein driving rods are connected with both sides of the coating head, respectively, sliders are connected to the driving rods and fit in slide rails, the slide rails extend in a scraping direction of the coating head, and the driving rods are driven by linear driving devices.

8. The in-situ flash evaporation film forming apparatus for the perovskite solar cell of claim 7, wherein the linear driving devices are linear motors, and each of the driving rods is driven by one linear motor.

9. The in-situ flash evaporation film forming apparatus for the perovskite solar cell of claim 1, wherein the cavity cover is driven by a cylinder.

10. The in-situ flash evaporation film forming apparatus for the perovskite solar cell of claim 1, wherein a fixing plate is disposed above the cavity cover, a guide hole is formed in the fixing plate, and a guide pillar is disposed on an upper surface of the cavity cover and fitted in the guide hole.
